(19) United States
(12) Patent Application Publication
(10) Pub. No.: US 2024/0421184 A1
(43) Pub. Date: Dec. 19, 2024

(54) SEMICONDUCTOR DEVICE AND METHOD OF FORMING THE SAME

(71) Applicant: Fujian Jinhua Integrated Circuit Co., Ltd., Quanzhou City (CN)

(72) Inventors: Janbo Zhang, Quanzhou City (CN); Yu-Cheng Tung, Quanzhou City (CN); Hsi-Chih Li, Quanzhou City (CN); Tsung-Yi Wu, Quanzhou City (CN)

(73) Assignee: Fujian Jinhua Integrated Circuit Co., Ltd., Quanzhou City (CN)

(21) Appl. No.: 18/516,963

(22) Filed: Nov. 22, 2023

(30) Foreign Application Priority Data
Jun. 16, 2023 (CN) 202310717063.8

(51) Int. Cl. H01L 29/06; H01L 29/66; H10B 12/00

(52) U.S. Cl. CPC H01L 29/0649; H01L 29/6656; H10B 12/0335; H10B 12/488

(57) ABSTRACT

In a semiconductor device and a method of forming the same, the semiconductor device includes a substrate, conductive layer structures, plug structures, spacers and stop layers. The plug structures are disposed between two of the conductive layer structures in a second direction perpendicular to the first direction. The spacers are disposed between the conductive layer structures and the plug structures. The stop layers are disposed on the spacers between the conductive layer structures and the plug structures and has a bottommost surface disposed between a bottom surface of the conductive layer structures and a bottom surface of the spacers. The plug structures comprise at least one protrusion member extending from the bottommost surface toward the conductive layer structure and disposed between the stop layer and the substrate. Accordingly, contact area between the plug structures and the substrate can be increased.

### BACKGROUND OF THE INVENTION

### 1. Field of the Invention

The present invention generally relates to a semiconductor device and a method of forming the same, and more particularly to a semiconductor device having a plug structure and a method of forming the same.

### 2. Description of the Prior Art

With the trend of miniaturization of various electronic products, semiconductor devices must be designed to meet the requirements of high integration and high density. For a dynamic random access memory (DRAM) with a trench gate structure, due to its advantage of having enlarged carrier channel length in common semiconductor substrate area so as to reduce current leakage in the capacitor structure, it has gradually replaced dynamic random access memory devices with planar gate structures under current development trend. Generally, a dynamic random access memory with a trench gate structure is an array area formed by a large number of memory cells for data storage. Each memory cell can be composed of transistor components and capacitor components in series to receive voltage data from word lines (WL) and bit lines (BL). With the increasing product requirements, higher and higher density of memory cells in the array area is also required, resulting in increasing difficulty and complexity in related manufacturing processes and designs. Therefore, conventional technologies or structures need to be improved to enhance efficiency and reliability of related memory devices.

### SUMMARY OF THE INVENTION

An object of the present invention is to provide a semiconductor device, in which a plurality of plug structures are arranged between adjacent conductive layer structures or between adjacent isolation structures. At least one protrusion member extending toward a corresponding conductive layer structure or toward a corresponding gate line is provided, so that the contact area between the plug structures and the substrate is enlarged, and the electrical connection between the storage node plugs and the transistor components thereunder is effectively improved. Therefore, the semiconductor device according to the present invention can have optimized component structure and efficiency, thereby improving the operational performance thereof.

An object of the present invention is to provide a method of forming a semiconductor device, in which a stop layer is formed on a spacer, and the stop layer is used as a lateral etching mask of a plug hole, thereby forming a plug hole extending toward a conductive layer structure or a gate line between adjacent conductive layer structures or adjacent isolation structures. Therefore, a bottom of each plug structure has at least one protrusion member extending toward the conductive layer structure or toward the gate line, thereby increasing contact area between the plug structure and the substrate. The method according to the present invention can form a semiconductor device with optimized structure and device efficiency.

For achieving the above-described object, according to an embodiment of the present invention, a semiconductor device includes a substrate, a plurality of conductive layer structures, a plurality of plug structures, a plurality of spacers and a plurality of stop layer. The substrate includes a plurality of active areas and a plurality of shallow trench isolation structures. The plurality of conductive layer structures extend parallel to each other on the substrate in a first direction, and cross over the plurality of active areas and the plurality of shallow trench isolation structures. The plug structures are disposed between two of the plurality of conductive layer structures in a second direction perpendicular to the first direction. The plurality of spacers are disposed between the conductive layer structures and the plug structures. The plurality of stop layers are disposed on the spacers between the conductive layer structures and the plug structures, and includes a bottommost surface disposed between a bottom surface of the plurality of conductive layer structures and a bottom surface of the plurality of spacers. The plurality of plug structures include at least one protrusion member, which extends from the bottommost surface of one of the plurality of stop layers toward one of the plurality of conductive layer structures and is disposed between the one of the plurality of stop layers and the substrate.

For achieving the above-described object, according to an embodiment of the present invention, a semiconductor device includes a substrate, a plurality of gate lines, a plurality of isolation structures, a plurality of plug structures and a plurality of insulating structures. The substrate includes a plurality of active areas and a plurality of shallow trench isolation structures. The plurality of gate lines are disposed in the substrate in a first direction and extend parallel to each other in a second direction perpendicular to the first direction. The plurality of isolation structures extend parallel to each other on the substrate in the second direction and are aligned with the plurality of gate lines, respectively. The plurality of plug structures are disposed between the plurality of gate lines in the first direction, wherein the plurality of plug structures comprise at least one protrusion member, which extends from a sidewall of one of the plurality of isolation structures toward one of the plurality of gate lines and is disposed between the one of the plurality of isolation structures and the substrate.

For achieving the above-described object, according to an embodiment of the present invention, a method of forming a semiconductor device includes the following steps: providing a substrate, the substrate comprising a plurality of active areas and a plurality of shallow trench isolation structures; forming a plurality of conductive layer structures on the substrate, the plurality of conductive layer extending parallel to each other in a first direction, and crossing over the plurality of active areas and the plurality of shallow trench isolation structures; forming a plurality of plug structures on the substrate, disposed between two of the plurality of conductive layer structures in a second direction perpendicular to the first direction; forming a plurality of spacers on the substrate, disposed between one of the plurality of conductive layer structures and one of the plurality of plug structures; and forming a plurality of stop layers, covering one of the plurality of spacers and is disposed between one of the plurality of conductive layer structures and one of the plurality of plug structures, the plurality of stop layers comprising a bottommost surface disposed between a bottom surface of the plurality of conductive layer structures and a bottom surface of the plurality of spacer. The plurality of plug structures include at least one protrusion member, which extends from the bottommost surface of the plurality of stop layers toward one of the plurality of conductive layer structures and is disposed between one of the plurality of stop layers and the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 and FIG. 2 are schematic diagrams illustrating a semiconductor device according to a first embodiment of the present invention, wherein

FIG. 1 is schematic top view of the semiconductor device; and

FIG. 2 is a schematic cross-sectional view of the semiconductor device taken along the A-A′ line of FIG. 1.

FIG. 3 to FIG. 8 are schematic diagrams illustrating a method of forming a semiconductor device according to an preferred embodiment of the present invention, wherein:

FIG. 3 is a schematic cross-sectional view of the semiconductor device after a spacer material layer is formed;

FIG. 4 is a schematic cross-sectional view of the semiconductor device after spacers are formed;

FIG. 5 is a schematic cross-sectional view of the semiconductor device after a stop material layer is formed;

FIG. 6 is a schematic cross-sectional view of the semiconductor device after stop layers are formed;

FIG. 7 is a schematic cross-sectional view of the semiconductor device after a first wet etching process is performed; and

FIG. 8 is a schematic cross-sectional view of the semiconductor device after a second wet etching process is performed.

FIG. 9 and FIG. 10 are schematic diagrams illustrating a semiconductor device according to a second embodiment of the present invention, wherein

FIG. 9 is a schematic cross-sectional view of the semiconductor device.

FIG. 10 is another schematic cross-sectional view of the semiconductor device.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

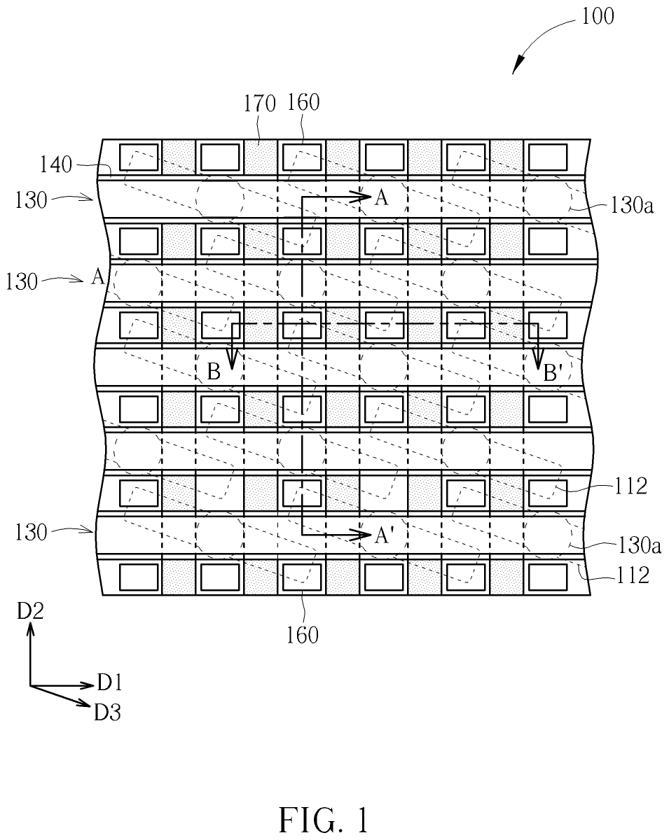

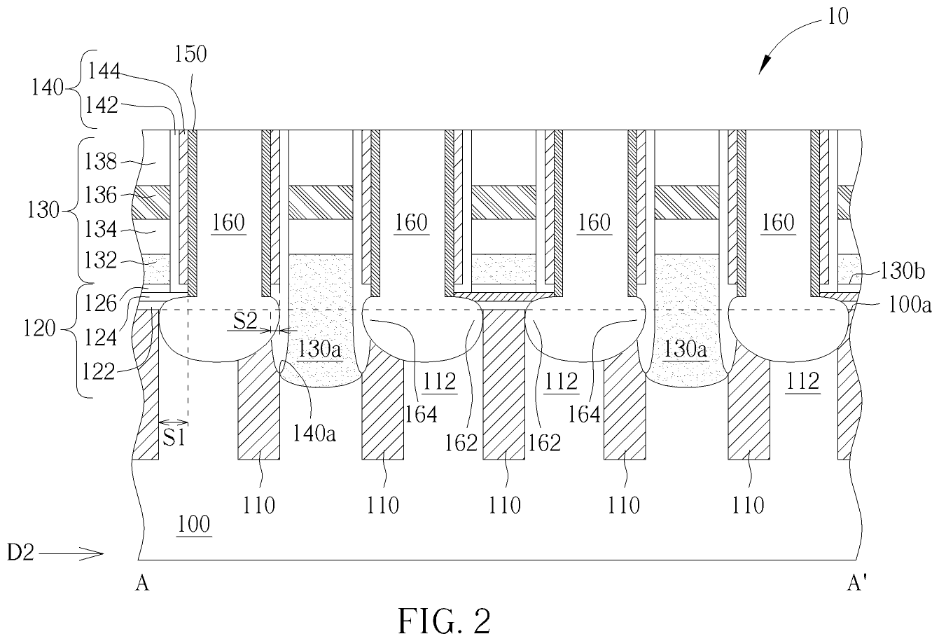

Please refer to FIG. 1 and FIG. 2, which are schematic diagrams illustrating a semiconductor device 10 according to a first embodiment of the present invention. The semiconductor device 10 includes a substrate 100, a plurality of conductive layer structures 130, a plurality of spacers 140, a plurality of stop layers 150, and a plurality of plug structures 160. The substrate 100 includes a plurality of shallow trench isolation structures 110 formed of a material including, for example, silicon oxide, and a plurality of active areas 112, which are disposed in the substrate 100. As shown in FIG. 1, the conductive layer structures 130 extend parallel to each other on the substrate 100 in a first direction D1, and cross over the plurality of active areas 112 and the plurality of shallow trench isolation structures 110. As shown in FIG. 2, each of the conductive layer structures 130 includes bit line contacts 130a (BLC), which partially extend into the substrate 100 to electrically connect the conductive layer structure 130 to a portion of the active areas 112. The plug structures 160 are also disposed on the substrate 100 and partially extend into the substrate 100, and thus the plug structures 160 are electrically connected to another portion of the active areas 112. As shown in FIG. 1 and FIG. 2, in a second direction D2 perpendicular to the first direction D1, each of the plug structures 160 is disposed between two adjacent conductive layer structures 130, and the plug structures 160 are electrically isolated from each other by the spacers 140, each of which is disposed between one of the conductive layer structures 130 and one of the plug structures 160. The stop layers 150 are disposed on the spacers 140, respectively, and each of the stop layers 150 is located between one of the plug structures 160 and one of the spacers 140 in the second direction D2, wherein the stop layers 150 comprise a bottommost surface disposed between a bottom surface 130b of the conductive layer structures 130 and a bottom surface 140a of the spacers 140. In an embodiment, the stop layers 150 are formed of a material including, for example but not limited to, an insulating material different from a material of the spacers 140, e.g., silicon oxynitride, silicon carbonitride, etc. In particular, each of the plug structures 160 includes at least one protrusion member, such as the protrusion member 162 and/or the protrusion member 164 as shown in FIG. 2. The protrusion member 162 and/or the protrusion member 164 extend from the bottommost surface of the corresponding stop layer 150 toward the adjacent conductive layer structure(s) 130, respectively, and are located between the corresponding stop layer(s) 150 and the substrate 100. In this way, the contact area between the plug structures 160 and the substrate 100 can be increased due to the arrangement of the protrusion member 162 and/or the protrusion member 164. The component structure and effects of the semiconductor device 10 can thus be effectively improved, thereby improving the operational performance of the semiconductor device 10.

In detail, in the second direction D2, the protrusion members 162 and 164 are respectively disposed at two opposite sides of each of the plug structures 160, and have different lengths S1 and S2 in the horizontal direction parallel to the top surface 100a of the substrate 100. As the protrusion member 164 is located adjacent to the contact 130a, it is preferred that the length S2 of the protrusion member 164 is smaller than the length S1 of the protrusion member 162 to avoid direct physical contact with the contact 130a and short circuit. The protrusion members 162 and 164 may, but not necessarily, at least partially overlap with the corresponding spacer 140 and the corresponding stop layer 150 in the vertical direction perpendicular to the top surface 100a of the substrate 100. It should be noted that, due to the disposition of the stop layer 150, the protrusion member 162 does not contact the spacer 140, and instead, the edge of the protrusion member 162 physically contacts the active area 112 and the shallow trench isolation structure 110 right under the conductive layer structure 130, as shown in FIG. 2. On the other hand, the edge of the protrusion member 164 physically contacts the shallow trench isolation structure 110 but also covers the spacer 140 on the sidewall of the contact 130a. The spacer 140 preferably has a composite layer structure including, for example, a first spacer 142 and a second spacer 144 sequentially disposed on the sidewalls of each of the conductive layer structures 130 in the horizontal direction. The edge of the protrusion member 164 physically contacts the first spacer 142 without contacting the second spacer 144. In an embodiment, the first spacer 142 and the second spacer 144 may, but not necessarily, be formed of different materials. The first spacer 142 may be formed of a material including silicon nitride, for example, and the second spacer 144 may be formed of a material including silicon oxide, for example. It should be easily understood by those of ordinary skill in the art that the structural configurations of the protrusion members 162 and/or the protrusion members 164 in the present invention are not specifically limited to those shown in FIG. 2, but may have other suitable configurations or shapes depending on practical requirements of the device. For example, in some embodiments, the protrusion members 162 and/or the protrusion members 164 may alternatively have uneven surfaces to further enhance the contact area between the plug structures 160 and the substrate 100.

As shown in FIG. 1, the active areas 112 in this embodiment are arranged in an array parallel to each other along a third direction D3, and the shallow trench isolation structures 110 surround all the active areas 112. Although the gate lines (not shown) disposed in the substrate 100 are not specifically depicted in the drawings associated with this embodiment, it should be easily understood by those of ordinary skill in the art that the extending directions of the active areas 112, the gate lines and the conductive layer structures 130 are all different, and the extending direction of the gate lines should be perpendicular to the extending direction, i.e., the first direction D1, of the conductive layer structures 130 while crossing over the active areas 112 and the conductive layer structures 130. In other words, the gate lines extend parallel to each other along the second direction D2, and a plurality of isolation structures 170 are disposed right above the gate lines to electrically isolate conductive layer structures 130 and/or plug structures 160. In this way, each of the contacts 130a is arranged between adjacent isolation structures 170 (or the gate lines). In one embodiment, the isolation structures 170 are formed of a material including, for example, but not limited to, an insulating material such as silicon nitride or silicon carbonitride.

As shown in FIG. 2, the semiconductor device 10 further includes an insulating layer 120 disposed on the top surface 100a of the substrate 100. The insulating layer 120 is located between the conductive layer structures 130 and the substrate 100 to electrically isolate the conductive layer structures 130 from components (such as the gate lines) arranged in the substrate 100. In an embodiment, the substrate 100 includes, for example, a silicon substrate, a silicon-containing substrate, an epitaxial silicon substrate, a silicon-on-insulator substrate or a substrate formed of another suitable material. The insulating layer 120 preferably but not necessarily includes composite material layers, e.g. a first layer 122 formed of a material including an insulating material such as silicon nitride, a second layer 124 formed of a material including an insulating material such as silicon oxide and a third layer 126 formed of a material including an insulating material such as silicon nitride stacked in sequence, and has, but not limited to, a nitride-oxide-nitride (NON) structure. In particular, but not necessarily, the protrusion members 162 are simultaneously in contact with two insulating materials, e.g., the materials of the silicon oxide layer 124 and the silicon nitride layer 122, included in the stop layers 150 and the insulating layer 120, while the protrusion members 164 are in contact with the materials included in both the stop layers 150 and the first spacers 142 but do not contact the insulating material included in the insulating layer 120. In addition, each of the conductive layer structures 130 further include a semiconductor layer 132, a barrier layer 134, a metal layer 136 and a cap layer 138 sequentially stacked on the substrate 100 from bottom to top. Furthermore, the contacts 130a are integrally formed with the semiconductor layers 132 of the conductive layer structures 130 of the same material. In one embodiment, the semiconductor layers 132 is formed of a material including, for example, doped polysilicon, doped amorphous silicon or another suitable semiconductor material; the barrier layer 134 is formed of a material including, for example, a conductive barrier material such as titanium and/or titanium nitride (TiN), tantalum (Ta) and/or tantalum oxide (TaN); the metal layer 136 is formed of a material including, for example, copper, aluminum, tungsten or another suitable low-resistivity conductive material; and the cap layer 138 is formed of a material including, for example, silicon oxide, silicon nitride or oxynitride.

In this configuration, the conductive layer structures 130 can be used as bit lines (BL) of the semiconductor device 10, the plug structures 160 can be used as storage node contacts (SNC) of the semiconductor device 10, and the gate lines can be used as buried word lines (BWL) of the semiconductor device 10. Therefore, the semiconductor device 10 in this embodiment can be used as a dynamic random access memory (DRAM) device, wherein at least one capacitor (not shown) subsequently arranged above the plug structures 160 and at least one transistor element (not shown) arranged in the substrate 100 constitute a unitary memory cell in the DRAM array for receiving voltage data from the bit lines, i.e. the conductive layer structures 130, and the buried word lines, i.e., the gate lines.

In this embodiment of semiconductor device 10, the bottom of each of the plug structures 160 is provided with at least one protrusion member, e.g., the protrusion member 162 and/or the protrusion member 164 shown in FIG. 2, extending from the bottommost surface of the corresponding stop layer 150 toward the corresponding conductive layer structure 130. As such, the contact area between the plug structures 160 and the substrate 100 can be effectively increased and the electrical connection between the storage node plugs, i.e., the plug structures 160, and the transistor components can be improved. Accordingly, the semiconductor device 10 has an optimized component structure and effects, thereby improving the operational performance of the semiconductor device 10.

In order to make those of ordinary skill in the art readily understand the features of the semiconductor device 10 according to the present invention, the method of forming the semiconductor device 10 according to an embodiment of the present invention will be further described below.

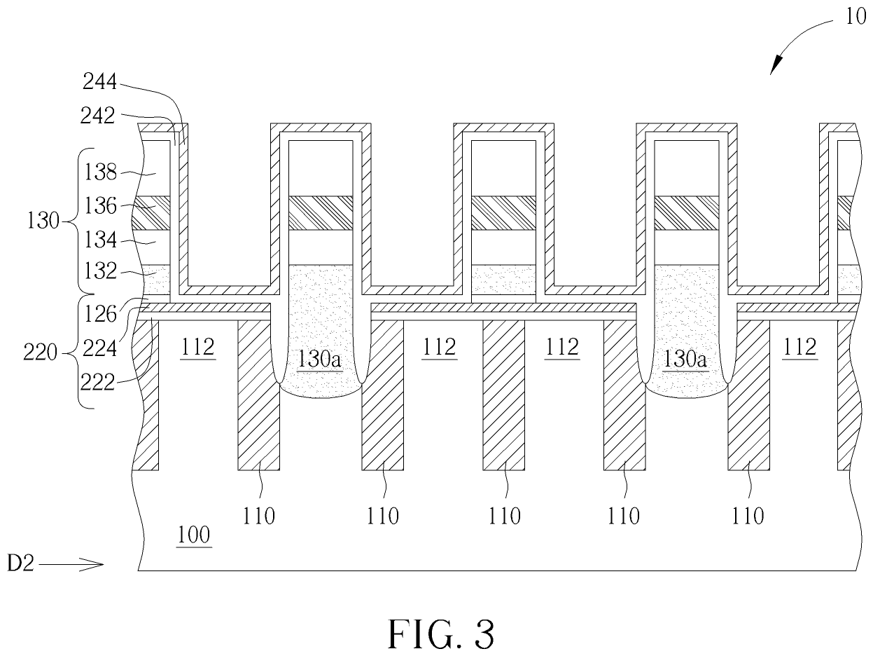

Please refer to FIG. 3 to FIG. 8, which are schematic diagrams illustrating a method of forming the semiconductor device 10 according to a preferred embodiment of the present invention. First, as shown in FIG. 3, a substrate 100 is provided, and shallow trench isolation structures 110 are formed in the substrate 100 to define a plurality of active areas 112. In one embodiment, the formation of the shallow trench isolation structures 110 includes, for example, forming a plurality of trenches (not shown) in the substrate 100 by way of an etching process, and then filling the trenches with at least one insulating material, e.g., silicon oxide. The resulting shallow trench isolation structures 110 have a surface flush with the top surface of the substrate 100, but it is not limited thereto.

Subsequently, an insulating material layer 220 is formed on the substrate 100. The insulating material layer 220 covers the active areas 112 and shallow trench isolation structures 110 in the substrate 100, and includes a first material layer 222 formed of a material including silicon nitride, for example, a second material layer 224 formed of a material including silicon oxide, for example, and a third layer 126 formed of a material including silicon nitride, for example, stacked in sequence from bottom to top. Conductive layer structures 130 are formed on the insulating material layer 220. It should be noted that before the conductive layer structures 130a are formed, the first material layer (not shown), the second material layer (not shown) and the third material layer (not shown) are formed on and cover the substrate 100 in an integral form. Then, the first material layer, the second material layer and the third material layer (not shown) are partially removed to form a plurality of contact holes (not shown). In an embodiment, the process of forming the conductive layer structures 130 and the contacts 130a includes, but is not limited to, the following steps. First, a semiconductor material (not shown and, for example, including polysilicon and doped amorphous silicon), a barrier material layer (not shown and, for example, including a conductive barrier material such as titanium and/or titanium nitride, tantalum and/or tantalum oxide), a conductive material layer (not shown and, for example, including a low resistivity conductive material such as copper, aluminum and tungsten) and a cover material layer (not shown) are sequentially formed on the substrate 100. Subsequently, a patterning process is performed to simultaneously form the conductive layer structures 130 and the contacts 130a.

On the other hand, during formation of the conductive layer structures 130, the third material layer is also partially removed to form the third layer 126. In this way, each of the conductive layer structures 130 and the third layer 126 disposed thereunder can have respective sidewalls substantially aligned with each other, as shown in FIG. 3. Then, two deposition processes are performed to sequentially form a first spacer material layer 242 and a second spacer material layer 244 on the conductive layer structures 130 and the substrate 100 to overlie the exposed surfaces of the conductive layer structures 130, the insulating material layer 220 and the contact 130a in a conformal manner. In an embodiment, the first spacer material layer 242 and the second spacer material layer 244 may, but not necessarily, include different insulating materials. The first spacer material layer 242 may be formed of a material including silicon nitride, for example, and the second spacer material layer 244 may be formed of a material including silicon oxide, for example.

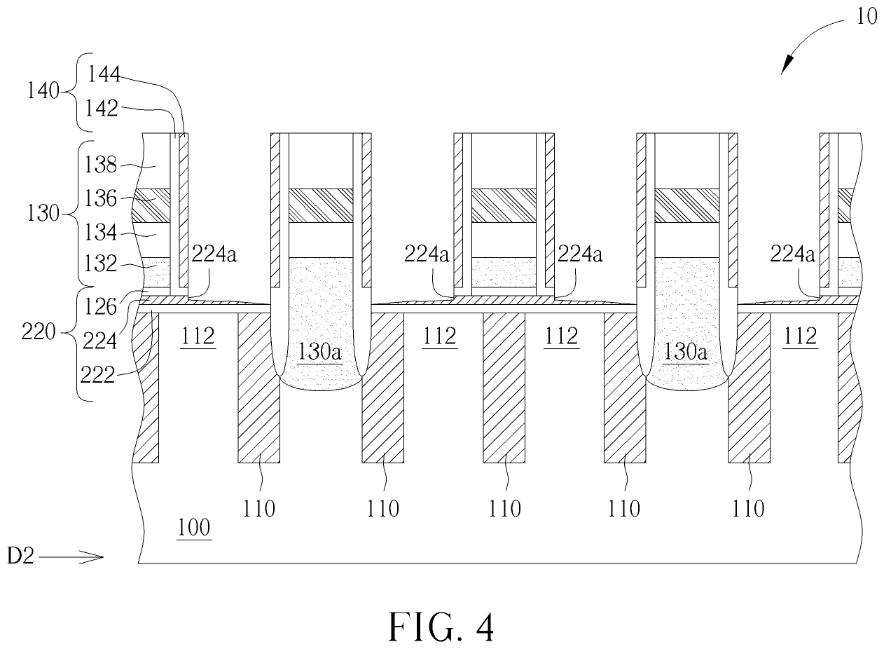

As shown in FIG. 4, an etching back process is performed to remove the second spacer material layer 244 and the first spacer material layer 242 on the top surfaces of the conductive layer structures 130 and the insulating material layer 220, thereby forming the first spacer 142 and the second spacer 144 on the side surfaces of each of the conductive layer structures 130 in sequence. In this way, the first spacer 142 and the second spacer 144 can jointly form the spacer 140. It should be noted that during the etching back process, the second material layer 224 of the insulating material layer 220 is also partially removed. The second material layer 224 adjacent to the side surfaces of each of the contacts 130a is preferably greatly removed, or even completely removed to expose the underlying first material layer 222. On the other hand, the second material layer 224 adjacent to each of the conductive layer structures 130 is partially removed until only about one-half to one-third of the original thickness of the second material layer 224 is left, so that a part, e.g., a half, of the sidewall 224a is exposed. Furthermore, the second material layer 224 disposed right under the first spacer 142 and the second spacer 144 may, but not necessarily, be completely remained, i.e., not removed at all.

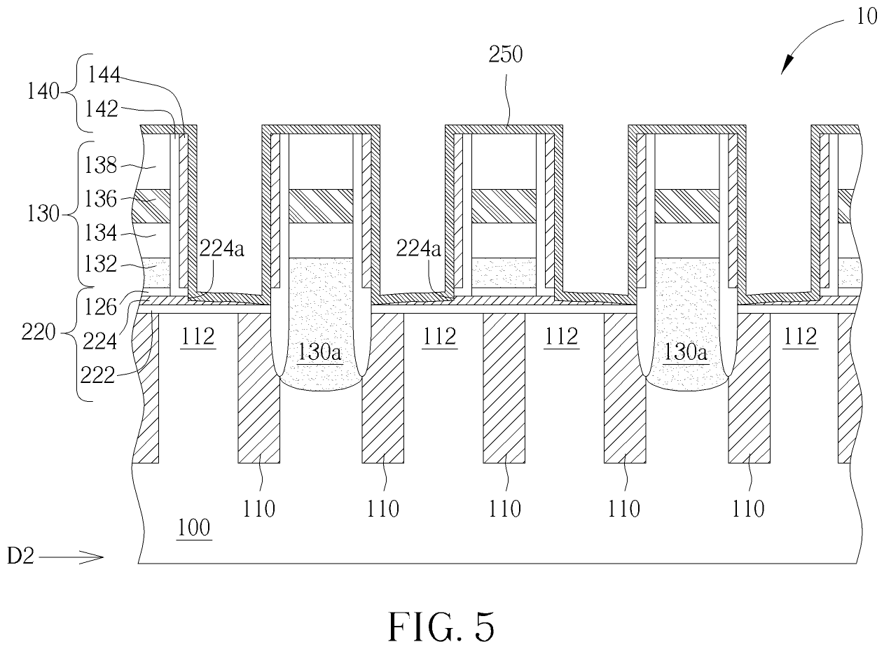

As shown in FIG. 5, another deposition process is performed to form a stop material layer 250, which conformally overlies the conductive layer structures 130 and the spacers 140. In detail, the stop material layer 250 continuously covers the top surfaces of the conductive layer structures 130, the top surfaces and sidewalls of the spacers 140 and the exposed surface of the remaining second material layer 224, and physically contacts the exposed parts of sidewalls 224a of the remaining second material layer 224. The stop material layer 250 further physically contacts the first spacers 142 overlying the sidewalls of the contacts 130a and the first material layer 222 exposed from the remaining second material layer 224. In an embodiment, the stop material layer 250 may, but not necessarily, be formed of a material different from the materials of the first spacer 142 and the second spacer 144, and the material of the stop material layer 250 may include, but not limited to, an insulating material such as silicon oxynitride, silicon carbonitride, etc.

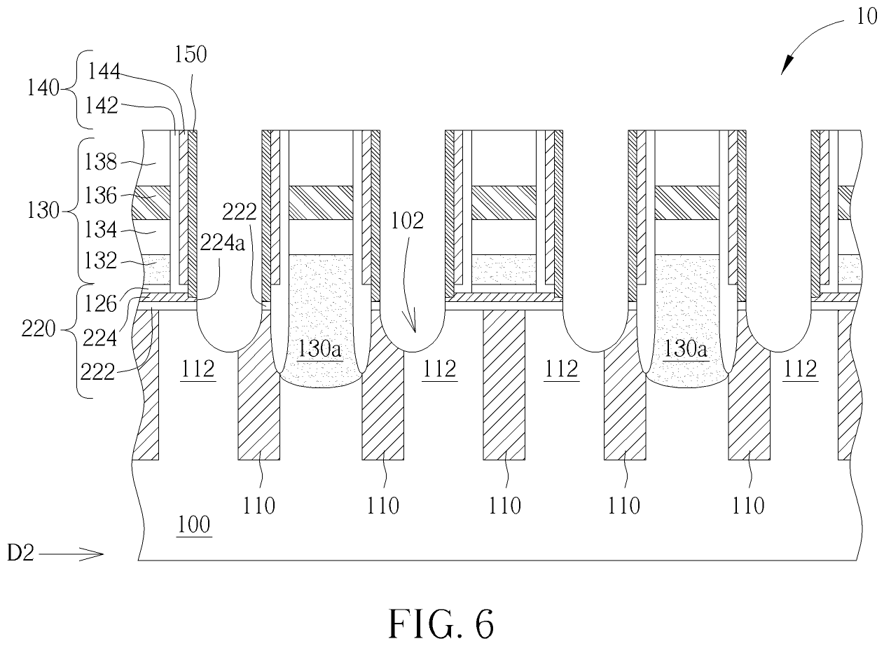

As shown in FIG. 6, another etching back process is performed to partially remove the stop material layer 250. A part of the stop material layer 250, which covers the top surfaces of the conductive layer structures 130, the top surfaces and sidewalls of the spacers 140 and the exposed surface of the remaining second material layer 224, is removed to form the stop layers 150. Meanwhile, during this etching back process, the remaining second material layer 224, the underlying first material layer 222 and the substrate 100 (including the active areas 112 and the shallow trench isolation structures 110) are also partially removed to form a plurality of holes 102 that can expose the active areas 112 and the shallow trench isolation structures 110. It should be noted that after this etching back process, the stop layers 150 adjacent to the conductive layer structures 130 still physically contacts the exposed partial sidewalls 224a of the remaining second material layer 224. The bottommost surfaces of the stop layers 150 physically contact the remaining second material layer 224, while the sidewalls of the stop layers 150 simultaneously are aligned with the sidewalls of the remaining second material layer 224 and the remaining first material layer 222. On the other hand, since the second material layer 224 adjacent to the contacts 130a has been completely removed in the etching back process of the first spacer material layer 242 and the second spacer material layer 244, the bottommost surfaces of the stop layers 150 adjacent to the contacts 130a physically contact the remaining first material layer 222, and the sidewalls of the stop layers 150 adjacent to the contacts 130a are flush with only the sidewalls of the remaining first material layer 222, as shown in FIG. 6.

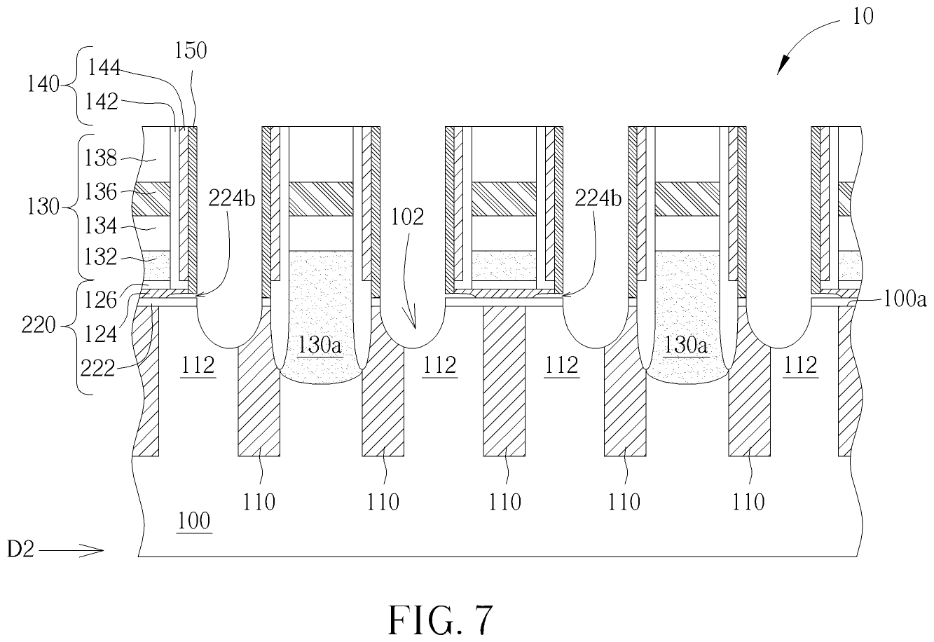

As shown in FIG. 7, after the stop layers 150 are formed, a first wet etching process is performed with the presence of the stop layers 150 to further laterally remove a part of the remaining second material layer 224. In detail, by way of the first wet etching process, a plurality of caves 224b are formed in the remaining second material layer 224, which extend from the exposed partial sidewalls 224a toward the conductive layer structures 130 and are located between the bottommost surfaces of the stop layers 150 and the top surface 100a of the substrate 100. Meanwhile, the second layer 124 is also formed. At this time, the sidewalls of the stop layers 150 are still flush with the sidewalls of the remaining first material layer 222. That is, by performing the first wet etching process, the second material layer 224 is selectively etched, so that the remaining second material layer 224 is formed with concave sidewalls, as shown in FIG. 7.

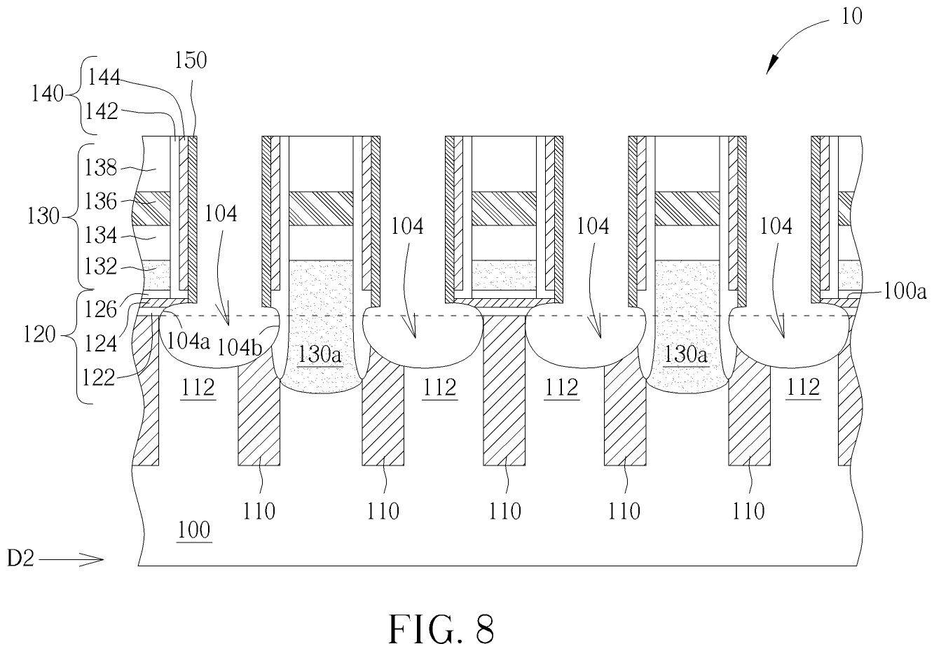

As shown in FIG. 8, a second wet etching process is performed with the presence of the stop layers 150. A part of the remaining first material layer 222 is further removed laterally, and a plurality of recesses extending from the caves 224b shown in FIG. 7 toward the conductive layer structures 130 and disposed between the bottommost surfaces of the stop layers 150 and the top surface 100a of the substrate 100 are formed in the remaining first material layer 222. Meanwhile, the first layer 122 is formed. Thus, the first layer 122, the second layer 124 and the third layer 126 together form an insulating layer 120 on the substrate 100 and between the top surface 100a of the substrate 100 and the conductive layer structures 130. On the other hand, during the second wet etching process, the exposed active areas 112, shallow trench isolation structures 110 and the first spacers 142 covering the sidewalls of the contacts 130a are further removed from the holes 102 as shown in FIG. 7. Finally, a plurality of plug holes 104 having a wider exposure range are formed. It should be noted that one side of each of the plug holes 104 is well configured to be in communication with the corresponding recess and the corresponding cave 224b shown in FIG. 7 to form a recessed portion 104a, which extends laterally into the insulating layer 120. On the other side of each of the plug holes 104, another recessed portion 104b extending laterally into the corresponding first spacer 142 is formed, as shown in FIG. 8. In this embodiment, the recessed portion 104a and the recessed portion 104b have different recessed degrees in the horizontal direction, wherein the recessed degree of the recessed portion 104b is preferably less significant than that of the recessed portion 104a as the first spacer 142 covering the side surface of the corresponding contact 130a has a relatively large thickness, so as to avoid exposing the contact 130a and the accompanying short circuit problems.

Subsequently, after the first wet etching process and the second wet etching process, another deposition process and another etching back process (not shown) are performed to form a plurality of plug structures 160 as shown in FIG. 1 and FIG. 2. The plug structures 160 fill the plug holes 104, respectively, and the recessed portions 104a and the recessed portions 104b are filled with parts of the plug structures 160 to form at least one protrusion member, such as a protrusion member 162 and/or a protrusion member 164 as shown in FIG. 2, so as to effectively increase the contact area between the plug structures 160 and the substrate 100.

By way of the above-described operations, the process of forming the semiconductor device 10 is completed. The semiconductor device 10 formed by the method according to this embodiment of the present invention can be used as a dynamic random access memory device. At least one capacitor (not shown) formed above the plug structures 160 and at least one transistor element (not shown) formed in the substrate 100 form the unitary memory cell in the dynamic random access memory array, and receive voltage data from the bit lines, i.e., the conductor structure 130 of the semiconductor device 10, and the word lines, i.e., the gate lines of the semiconductor device 10.

According to the method of forming the semiconductor device 10 according to this embodiment of the present invention, the stop layers 150 are formed on the spacers 140, respectively, and the stop layers 150 are used as lateral etching masks in the first wet etching process and the second wet etching process in order to form recessed portions 104a and/or recessed portions 104b, which extend from the bottommost surfaces of the stop layers 150 toward the conductive layer structures 130 at the bottom of the plug holes 104 between adjacent conductive layer structures 130. In this way, the plug structures 160 formed in the plug holes 104 can have corresponding protrusion members 162 and/or protrusion members 164, so that the contact area between the plug structures 160 and the substrate 100 can be effectively increased, Meanwhile, the electrical connection between the storage node plugs (plug structures 160) of the semiconductor device 10 and the transistor components can be improved. Therefore, the semiconductor device 10 manufactured by the method of forming the semiconductor device 10 in this embodiment has optimized component structure and effects, and achieving good operational performance.

Those of ordinary skill in the art should readily understand that a semiconductor device and a method of forming the same according to the present invention may have alternative forms or can be achieved by alternative means, without being limited to the foregoing, on the premise of meeting the practical requirements of products. Other embodiments or variations of the semiconductor device and the method of forming the same according to the present invention will be further described below. In order to simplify the descriptions, the following descriptions mainly focus on the differences between embodiments, and will not repeat the similarities. Furthermore, the same components in various embodiments of the present invention are labeled with the same reference numerals to facilitate mutual comparison among various embodiments.

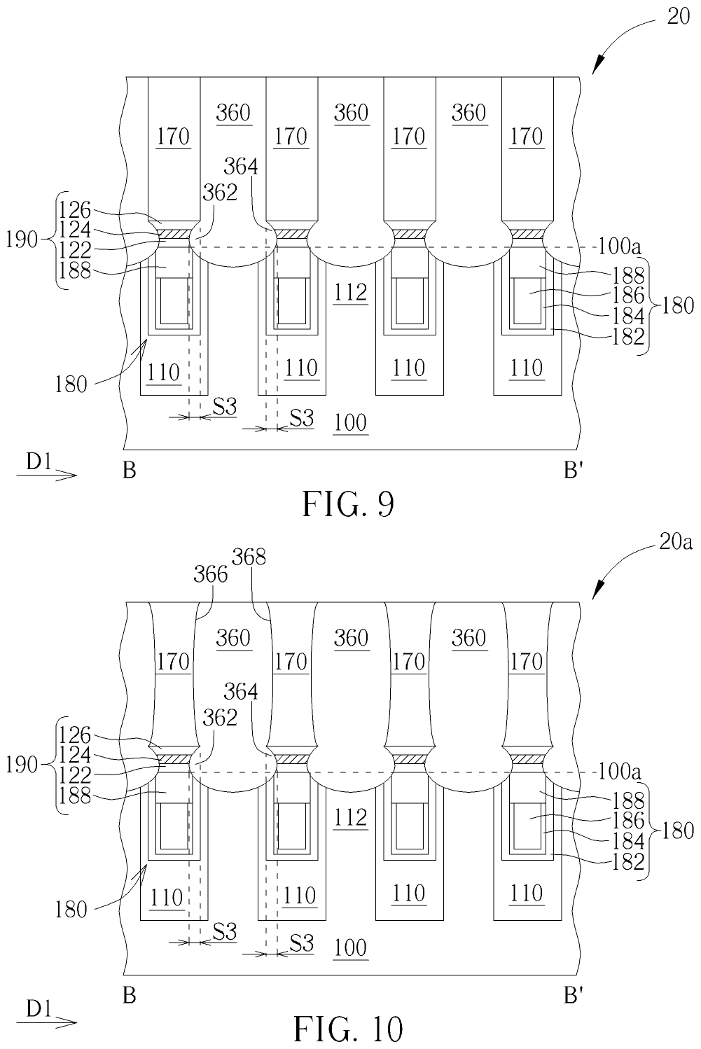

Please refer to FIG. 9 and FIG. 10, which are schematic diagrams illustrating a semiconductor device 20 and a semiconductor 20a, respectively, according to a second embodiment of the present invention. Each of the semiconductor devices 20 and 20a in this embodiment also include a substrate 100, a plurality of isolation structures 170 and a plurality of plug structures 360, wherein the substrate 100 also includes a plurality of shallow trench isolation structures 110 formed of a material including silicon oxide, for example, and a plurality of active areas 112 arranged therein. The main difference between the semiconductor devices 20 and 20a and the semiconductor device in the above-described first embodiment is that each of the plug structures 360 includes at least one protrusion member, e.g., a protrusion member 362 and/or a protrusion member 364 as shown in FIGS. 9 and 10 or a protrusion member 366 and/or a protrusion member 368 as shown in FIG. 10, which extend toward the gate line 180 provided in the substrate 100. Although the drawings in connection with this embodiment is only a schematic cross-sectional view, and the conductive layer structures 130 and the stop layers 150 are not specifically depicted in the drawings, it should be readily understood by those of ordinary skill in the art that the semiconductor devices 20 and 20a shown in FIG. 9 or FIG. 10 should be able to generally correspond to the cross-sectional structure taken along the section line B-B′ in FIG. 1, in which the semiconductor device in connection with the first embodiment is illustrated. In other words, the specific component configurations of the semiconductor devices 20 and 20a in this embodiment can be understood by synchronously referring to the first embodiment of semiconductor device described above with reference to FIG. 1.

In detail, the plurality of gate lines 180 extend in the substrate 100 in parallel with each other in the second direction D2 as shown in FIG. 1, while interleaving with the plurality of shallow trench isolation structures 110 and the plurality of active areas 112. The plurality of isolation structures 170 are disposed right above the gate lines 180, respectively, to electrically isolate adjacent components such as the conductive layer structures 130 and the plug structures 160 shown in FIG. 1. In other words, as shown in FIG. 9, in the first direction D1 perpendicular to the second direction D2, the gate lines 180 are respectively disposed in the substrate 100, and the isolation structures 170 are respectively disposed above and aligned with the gate lines 180. Meanwhile, the plug structures 360 are disposed between adjacent isolation structures 170 (also gate lines 180). Each of the gate lines 180 includes a dielectric layer 182, a gate dielectric layer 184, a gate electrode 186 and a cap layer 188 stacked in sequence, wherein the surface of the cap layer 188 is flush with the top surface 100a of the substrate 100, so that each of the gate lines 180 can be used as a buried word line of the semiconductor device 20. In a subsequent process, a transistor device (not shown) can be further formed in the substrate 100. In one embodiment, the method of forming the gate lines 180 includes, but is not limited to, the following steps. For example, a plurality of trenches (not shown) that can simultaneously penetrate through the plurality of active areas 112 and the plurality of shallow trench isolation structures 110 are formed. Then, in each of the trenches, the dielectric layer 182 covering the entire surface of the trench, a gate dielectric layer 184 covering the surface of a lower part of the trench, a gate electrode 186 filling the lower part of the trench and a cap layer filling the upper part of the trench are sequentially formed.

It should be noted that the semiconductor device 20 further includes an insulating layer 120 disposed between one of the gate lines 180 and one of the isolation structures 170, wherein the sidewall of the isolation structure 170 is flush with t the sidewall of the third layer 126 of the insulating layer 120. The cap layer 188 of the gate line 180 and the first layer 122, the second layer 124 and the third layer 126 of the insulating layer 120 all include insulating materials, and together form an insulating structure 190 between the isolation structure 170 and the gate line 180. In this embodiment, each of the plug structures 360 includes a protrusion member 362 and/or a protrusion member 364 extending from the sidewall of the isolation structure 170 toward the gate line 180 and disposed between the isolation structure 170 and the substrate 100, as shown in FIG. 9. In this way, each of the protrusion members 362 and/or 364 partially overlaps the upper isolation structure 170 and the lower gate line 180 in the vertical direction perpendicular to the top surface 100a of the substrate 100, and physically contact the cap layer 188 of the gate line 180 and the first layer 122, the second layer 124 and the third layer 126 of the insulating layer 120 at the same time. In this embodiment, the protruding member 362 and the protruding member 364 are respectively arranged at two opposite sides of each of the plug structures 360 in a symmetrical manner and may, but not limited to, have the same length S3 in the horizontal direction parallel to the top surface 100a of the substrate 100.

In this embodiment, the method of forming the protrusion members 362 and/or the protrusion members 364 includes, but is not limited to, the following steps. First, after forming the stop layers 150 as shown in FIG. 6, a first wet etching process and a second wet etching process are sequentially performed so as to laterally remove a part of the second material layer 224, as shown in FIG. 7, and a part of the first material layer 222, as shown in FIG. 8, thereby forming a plurality of recessed portions (not shown) extending from the sidewalls of the isolation structures 170 toward the gate lines 180. It should be noted that since the cap layer 188 of the gate line 180 and the first layer 122 of the insulating layer 120 include similar insulating materials, a part of the cap layer 188 will be removed at the same time when the second wet etching process is performed. As such, each of the recessed portions can partially expose the corresponding cap layer 188. Subsequently, a deposition process and an etching back process are performed to form the plug structures 360 as shown in FIG. 9. The plug structures 360 include protrusion members 362 and/or protrusion members 364, each of which physically contacts the cap layer 188, the first layer 122, the second layer 124 and the third layer 126 at the same time.

Alternatively, in another embodiment, the cap layer 188 of the gate line 180, the isolation structure 170 (including silicon nitride, for example) and the first layer 122 of the insulating layer 120 all include similar insulating materials. Therefore, a part of the isolation structure 170 is removed at the same time when the second wet etching process is performed, so as to form another recessed portion (not shown) on the sidewall of the isolation structure 170. Thus, after subsequent deposition and etching back processes, the plug structures 360 as shown in FIG. 10 are formed. Each of the plug structures 360 includes not only the protrusion members 362 and/or 364, which are in physical contact with the cap layer 188 of the gate line 180 and the first layer 122, the second layer 124 and the third layer 126 of the insulating layer 120 at the same time, but also the protrusion members 366 and/or 368, which extend from the sidewall of the isolation structure 170 toward the gate line 180.

In this configuration, with the disposition of the protrusion members 362 and 364 and/or the disposition of the protrusion members 366 and 368, the contact area between the plug structures 360 and the substrate 100 can be increased and the electrical connection between the storage node plugs, i.e., the plug structures 360, of the semiconductor devices 20 and 20a and the transistor components can be effectively improved. Therefore, the semiconductor devices 20 and 20a have optimized component structures and effects, thereby improving the operational performance thereof. The semiconductor devices 20 and 20a in this embodiment are described with the protrusion members 362 and 364 and/or the protrusion members 366 and 368 being included in the plug structure 360 and each extending from the sidewall of the isolation structure 170 toward the gate line 180. Nevertheless, it should be readily understood by those of ordinary skill in the art that the recessed portions 104a and 104b as shown in FIG. 8 as well as the recessed portions of the semiconductor device (not shown) in the alternative embodiment can also be formed in the first wet etching process and the second wet etching process. In this way, after the subsequent deposition and etching back processes, each of the plug structures in this semiconductor device may include protrusion members 162 and 164 (FIG. 2) extending from the bottommost surfaces of the stop layers 150 toward the corresponding conductive layer structures 130, in addition to the protrusion members 362 and 364 and/or protrusion members 366 and 368, each of which extends from the sidewall of the isolation structure 170 toward the corresponding gate line 180. In this way, the contact area between the plug structures 360 and the substrate 100 can be increased, thereby effectively improving the operational performance of the semiconductor device.

To sum up, a semiconductor device according to the present invention is provided with a plurality of plug structures between adjacent conductive layer structures or between adjacent isolation structures. The bottom of each plug structure is provided with at least one protrusion member extending toward the corresponding conductive layer structure and/or toward the corresponding gate line, thereby increasing the contact area between the plug structures and the substrate and effectively improving the electrical connection between the storage node plugs and the transistor components disposed thereunder. Therefore, the semiconductor device according to the present invention can have optimized component structure and effects, thereby improving the operational performance of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate comprising a plurality of active areas and a plurality of shallow trench isolation structures;
a plurality of conductive layer structures extending parallel to each other on the substrate in a first direction, and crossing over the plurality of active areas and the plurality of shallow trench isolation structures;
a plurality of plug structures, disposed between two of the plurality of conductive layer structures in a second direction perpendicular to the first direction;
a plurality of spacers, disposed between the conductive layer structures and the plug structures; and
a plurality of stop layers, disposed on the spacers between the conductive layer structures and the plug structures, and comprises a bottommost surface disposed between a bottom surface of the plurality of conductive layer structures and a bottom surface of the plurality of spacers;
wherein the plurality of plug structures comprise at least one protrusion member, which extends from the bottommost surface of one of the plurality of stop layers toward one of the plurality of conductive layer structures and is disposed between the one of the plurality of stop layers and the substrate.

2. The semiconductor device according to claim 1, wherein the at least one protrusion member is kept apart from the plurality of spacers and physically contacts one of the plurality of active areas and one of the plurality of shallow trench isolation structures disposed right under the one plurality of conductive layer structures at the same time.

3. The semiconductor device according to claim 1, wherein the at least one protrusion member physically contacts one of the plurality of spacers and one of the plurality of shallow trench isolation structures at the same time.

4. The semiconductor device according to claim 1, wherein the at least one protrusion member at least partially overlaps one of the plurality of spacers and one of the plurality of stop layers in a direction perpendicular to a top surface of the substrate.

5. The semiconductor device according to claim 1, wherein one of the plurality of plug structures comprises two protrusion members disposed at opposite sides thereof, respectively, and lengths of the two protrusion members are different in a direction parallel to a top surface of the substrate.

6. The semiconductor device according to claim 1, further comprising:
an insulating layer disposed on the substrate and disposed between the plurality of conductive layer structures and the substrate, wherein the insulating layer is formed of a composite material comprising at least two insulating materials, and the at least one protrusion member contacts the two insulating materials at the same time.

7. The semiconductor device according to claim 1, further comprising:
a plurality of gate lines extending parallel to each other in the substrate in the second direction;
a plurality of isolation structures disposed on the substrate in the second direction and aligned with the plurality of gate lines, respectively; and
a plurality of insulating structures disposed on the substrate, disposed between one of the plurality of isolation structures and one of the plurality of gate lines, wherein the plurality of plug structures comprise at least another protrusion member, which extends from a sidewall of one of the plurality of isolation structures toward one of the plurality of gate lines and is disposed between the one of the plurality of isolation structures and the substrate.

8. The semiconductor device according to claim 7, wherein the at least another protrusion member partially overlaps the one of the plurality of isolation structures and the one of the plurality of gate lines in a direction perpendicular to a top surface of the substrate.

9. The semiconductor device according to claim 7, wherein the insulation structures comprise a capping layer disposed in the substrate and a first layer, a second layer and a third layer disposed on the substrate, and the at least another protrusion member physically contacts the capping layer, the first layer, the second layer and the third layer at the same time.

10. A semiconductor device, comprising:
a substrate comprising a plurality of active areas and a plurality of shallow trench isolation structures;
a plurality of gate lines disposed in the substrate in a first direction and extending parallel to each other in a second direction perpendicular to the first direction;
a plurality of isolation structures extending parallel to each other on the substrate in the second direction and aligned with the plurality of gate lines, respectively; and
a plurality of plug structures disposed between the plurality of gate lines in the first direction, wherein the plurality of plug structures comprise at least one protrusion member, which extends from a sidewall of one of the plurality of isolation structures toward one of the plurality of gate lines and is disposed between the one of the plurality of isolation structures and the substrate.

11. The semiconductor device according to claim 10, wherein the at least one protrusion member partially overlaps the one of the plurality of isolation structures and the one of the plurality of gate lines in a direction perpendicular to a top surface of the substrate.

12. The semiconductor device according to claim 10, further comprising:
a plurality of insulating structures disposed on the substrate and located between the plurality of isolation structures and the plurality of gate lines, respectively, wherein the plurality of insulating structures comprise a capping layer disposed in the substrate and a first layer, a second layer and a third layer disposed on the substrate, and the at least one protrusion member physically contacts the capping layer, the first layer, the second layer and the third layer at the same time.

13. The semiconductor device according to claim 12, wherein the sidewall of the one of the plurality of isolation structures is aligned with a sidewall of the third layer.

14. The semiconductor device according to claim 10, wherein the sidewall of the one of the plurality of isolation structures comprises a recessed portion, and a part of the plurality of plug structures is disposed in the recessed portion.

15. A method of forming a semiconductor device, comprising:
providing a substrate, the substrate comprising a plurality of active areas and a plurality of shallow trench isolation structures;
forming a plurality of conductive layer structures on the substrate, the plurality of conductive layer extending parallel to each other in a first direction, and crossing over the plurality of active areas and the plurality of shallow trench isolation structures;
forming a plurality of plug structures on the substrate, disposed between two of the plurality of conductive layer structures in a second direction perpendicular to the first direction;
forming a plurality of spacers on the substrate, disposed between one of the plurality of conductive layer structures and one of the plurality of plug structures; and
forming a plurality of stop layers, covering one of the plurality of spacers and is disposed between one of the plurality of conductive layer structures and one of the plurality of plug structures, the plurality of stop layers comprising a bottommost surface disposed between a bottom surface of the plurality of conductive layer structures and a bottom surface of the plurality of spacers;
wherein the plurality of plug structures comprise at least one protrusion member, which extends from the bottommost surface of the plurality of stop layers toward one of the plurality of conductive layer structures and is disposed between one of the plurality of stop layers and the substrate.

16. The method according to claim 15, further comprising:
forming an insulating layer on the substrate, the insulating layer being disposed between the plurality of conductive layer structures and the substrate, wherein the insulating layer is formed of a composite material comprising at least two insulating materials, and the at least one protrusion member contacts the two insulating materials at the same time.

17. The method according to claim 16, wherein forming the insulating layer further comprises:
forming an insulating material layer on the substrate, the insulating material layer covering the plurality of active areas and the plurality of shallow trench isolation structures and comprising a first material layer, a second material layer and a third material layer stacked in sequence; and
etching off a part of the second material layer while forming the plurality of spacers.

18. The method according to claim 17, further comprising:
performing a first wet etching process to laterally remove a part of the second material layer;
performing a second wet etching process to laterally remove a part of the first material layer, thereby forming a recessed portion in the insulating layer; and
forming the plurality of plug structures after the first wet etching process and the second wet etching process, wherein a part of the plurality of plug structures fills the recessed portion to form the at least one protrusion member.

19. The method according to claim 18, wherein forming the plurality of stop layers comprises:
forming a stop material layer on the plurality of spacers, the stop material layer covering sidewalls of the plurality of spacers; and
partially removing the stop material layer to form the plurality of stop layers, wherein the plurality of stop layers are formed before the first wet etching process and the second wet etching process.

20. The method according to claim 15, further comprising:
forming a plurality of gate lines in the substrate in a first direction, the plurality of gate lines extending parallel to each other in the second direction;
forming a plurality of isolation structures on the substrate, the plurality of isolation structures extending parallel to each other in the second direction and aligned with the plurality of gate lines, respectively; and
forming a plurality of insulating structures on the substrate, the plurality of insulating structures being located between the plurality of isolation structures and the plurality of gate lines, respectively, wherein the plurality of plug structures comprise at least another protrusion member, which extends from a sidewall of one of the plurality of isolation structures toward one of the plurality of gate lines and is disposed between the one of the plurality of isolation structures and the substrate.
